(19) United States
(12) Patent Application Publication
(10) Pub. No.: US 2008/0259983 A1
(43) Pub. Date: Oct. 23, 2008

(54) SEMICONDUCTOR QUANTUM CASCADE LASER AND SYSTEMS AND METHODS FOR MANUFACTURING THE SAME

(76) Inventors: Mariano Troccoli, Paris (FR); Gloria Emilia Hofler, Sunnyvale, CA (US)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/952,732

(22) Filed: Dec. 7, 2007

Related U.S. Application Data
(60) Provisional application No. 60/869,280, filed on Dec. 8, 2006.
(60) Provisional application No. 60/981,084, filed on Oct. 18, 2007.

(51) Int. Cl. H01S 5/00

(52) U.S. Cl. 372/44.011; 372/45.012

(57) ABSTRACT

A bipolar quantum cascade (QC) laser includes a p-n junction disposed adjacent to an active/injection region of semiconductor layers. Systems that make use of such QC lasers and methods for manufacturing such QC lasers are also described.

### RELATED APPLICATIONS

This application is a non-provisional of, incorporates by reference and claims priority to U.S. Provisional Patent Applications 60/869,280, filed 8 Dec. 2006 and 60/981,084, filed 18 Oct. 2007.

### FIELD OF THE INVENTION

The present invention relates to semiconductor lasers, more particularly to quantum cascade semiconductor lasers having improved efficiency,

### BACKGROUND

Quantum cascade (QC) laser operation is explained by Federico Capasso, et al., in U.S. Pat. Nos. 5,457,709; 5,509,025; 5,570,386; 5,727,010; 5,745,516; and 5,936,989, each of which is incorporated herein by reference. Unlike typical inter-band (i.e., bipolar) semiconductor lasers that emit electromagnetic radiation through the recombination of electron-hole pairs across a material band gap, QC lasers are unipolar and laser emission is achieved through the use of inter-subband transitions in a repeated stack of very thin layers of semiconductor materials (i.e., a superlattice). Layer thicknesses in this stack must be carefully controlled in order to maintain a population inversion between adjacent subbands, which is necessary for laser emission.

State-of-the-art QC lasers (examples of which are described in F. Capasso et al., “Quantum Cascade Lasers: Ultrahigh-Speed Operation, Optical Wireless Communication, Narrow Linewidth, and Far-Infrared Emission”, IEEE J. Quantum Electron, v. 38, p. 511 (2002)) are only recently being made to operate in continuous mode (CW) at room temperature (typically 25° C.). See, e.g., L. Diehl et al., “High-temperature continuous wave operation of strain-balanced quantum cascade lasers grown by metal organic vapor-phase epitaxy”, Appl. Phys. Lett. v. 89, p. 08110 (2006). One of the main obstacles towards the realization of continuously operating QC lasers is their low electro-optical conversion efficiency, typically in the 2-5% range. This means that in the best cases to date, lasers that are able to emit more than 100 mW of optical power need to dissipate an electrical power in the 2-6 W range. This makes heat sinking and packaging a challenging issue.

Typical QC lasers are based on the InP material system, where the active region (i.e., the superlattice) is formed by alternating layers of two material types, for example an AlInAs and GaInAs lattice .matched to the InP substrate. An active core then consists of several (typically up to 40 or more) such active regions and their associated injector regions, which can be identical or grouped in different sets in order to achieve high gain and good optical mode overlap. Each repeating region consisting of an entire active region/injection region multilayer may be considered as a stage. The rest of the waveguide is typically created by the InP lower buffer layer and by a top cladding layer, which is also InP.

As indicated above, all the layers forming the QC laser material are of the same conductivity type, i.e., the lasers are unipolar devices, and so far only n-type devices have shown laser operation. Prior attempts to fabricate p-i-n type QC lasers have not been very successful. J. Faist et al., “A Quantum Cascade Laser Based on an n-i-p-i Superlattice”. IEEE Photon. Technol. Lett. 12(3), p. 263 (2000).

FIGS. 1A and 1B illustrate a conventional QC laser structure. FIG. 1A is a simplified schematic of the different layers of a QC laser. The epitaxial layers indicated in this chart are sequentially grown on a semiconductor substrate. As shown, an n-type InP substrate 10 serves as a foundational layer and an n-type InP buffer layer 12 is grown thereover. The multilayer active region/injector region 14 of the laser is disposed between n⁻-type InGaAs waveguide layers 16a, 16b. The multilayer active region/injector region 14 includes an active region 14a, made up of the QC materials (for example, n⁻-doped InGaAs and InGaAs), and an injector region (for example n-doped InGaAs) 14b. The n-type active core may include 40 or so such active region/injector region multilayer structures. An n⁻-type InP cladding layer 18 and an n⁺-type InGaAs top contact layer 20 complete the structure.

FIG. 1B illustrates a partial schematic of the semiconductor electronic band structure of a multilayer active region/injector region 22 of a QC laser, including two radiative transition regions (or active regions) 24a, 24b separated by an injector region 26. In this example, an n-type active region was chosen and the conduction band is shown. The straight vertical lines indicate interfaces between the layers of different QC materials (for example, InGaAs and InAlAs) in the active regions while the electron wavefunctions, which are related to the probability finding an electron at a particular location along the horizontal axis, are shown by the curved lines on the horizontal lines labeled 1, 2, and 3. Each wavefunction has a potential energy associated with it that is proportional to the vertical displacement shown by the energy levels depicted as the horizontal lines labeled 1, 2, and 3.

Electrons can be injected in the structure by electrical contacts to the laser device and lose their energy by means of quantum transitions between the wavefunctions of different energy levels within an active region 24a, 24b (e.g., as shown by transitions from the third energy level to the second energy level). Once the electrons transition to the lower, second energy level within an active region they can cascade to the third energy level of the next active region (represented as energy level 1 in the illustration), which can be at a slightly lower energy than the second energy level of the previous active region. In that next active region, the electrons can transition to the second energy level of the subject region, and the cascading process continues for each successive active region. At least one of these transitions will produce mid-infrared (mid-IR) radiation (indicated by the wavy vertical lines) which can then be amplified to generate laser action.

All of the above-described electron transitions take place in materials of the same conductivity type. Hence, to make tills laser operate it is necessary to provide an external electronic potential or bias to the structure that is at least equal to the sum of all the radiative transitions energies. This is typically on the order of about 7 volts. To enable QC laser proliferation into a wider range of products and systems, a more efficient QC laser that can have a low-cost, compact, low-power package is needed.

### SUMMARY OF THE INVENTION

In one embodiment, a QC laser includes a first stack of semiconductor layers of a first conductivity type, an active/injection region of semiconductor layers, and a base region between the first stack and the active/injection region, the base region containing at least one layer of a second conductivity type. The first stack of semiconductor layers may be an emitter for the active/injection region and the first stack and base may form a tunnel junction. The base region of the QC laser may include a more heavily doped layer and a more lightly doped layer, each of the second conductivity type

In some cases, a plurality of active/injection regions may be included. Second stacks of semiconductor layers of the first conductivity type may be located between each of the plurality of active/injection regions. Each of the second stacks of semiconductor layers may include a collector for a respective one of the active/injection regions and an emitter for an adjacent one of the active/injection regions. The number of active/injection regions may be between 2 and 100, inclusive, more specifically between 5 and 35, inclusive

A further embodiment of the present invention provides a laser having a plurality of active/injection regions of a first conductivity type, each active/injection region having two or more coupled quantum wells having at least a second and a third energy level for charge carriers of the first conductivity type, the third energy level being higher in energy than the second energy level; and a plurality of base layers of a second conductivity type, each base layer separating respective pairs of the active/injection regions from one another. Electrical contacts may be coupled to apply a voltage across the active/injection regions.

At least some of the charge carriers of the first conductivity type may undergo a radiative transition from the third enemy level to the second energy level within at least one of the active/injection regions. Such charge carriers of the first conductivity type may then be transferred from the second energy level of a preceding one of the active regions to the third energy level of a succeeding one of the active/injection regions, said second energy level of the preceding one of the active/injection regions being higher in energy than said third energy level of the succeeding one of the active/injection regions.

Tunnel junctions may be located between respective pairs of the active/injection regions. Bach tunnel junction may regenerate carriers of first conductivity type. Tunnel junctions may be interleaved between multiple repetitions (e.g., more than two) of active/injection regions in order to decrease optical absorption effects of highly-doped layers in a waveguide core of the laser.

A further embodiment of the present invention provides a sensing system having an optical engine with at least one QC laser that includes a first stack of semiconductor layers of a first conductivity type, an active/injection region of semiconductor layers, and a base region between the first stack of semiconductor layers and the active/injection region, the base region containing at least one layer of a second conductivity type. The sensing system may be a chemical sensing system and/or may include a cell capable of containing a test sample (e.g., a gas, a liquid, or a solid). The test, sample may be a remote target positioned more than about 0.1 m away from the laser.

The sensing system may include a detection assembly configured to measure changes in at least one of optical transmission, absorption, or reflection of the test sample. Alternatively, or in addition, the detection assembly may be configured to measure one of intrinsic or extrinsic physical parameters of the test sample.

Another embodiment of the present invention provides an imaging system having an optical engine with at least one QC laser having a first stack of semiconductor layers of a first conductivity type, an active/injection region of semiconductor layers, and a base region between the first stack of semiconductor layers and the active/injection region, the base region containing at least one layer of a second conductivity type.

Further, a bipolar QC laser may be manufactured by forming a first stack of semiconductor layers of a first conductivity type, forming a base region of a second conductivity type above the first stack of semiconductor layers, and forming an active/injection region above the base region. Alternatively, a bipolar QC laser may be manufactured by forming first and second stacks of semiconductor layers of a first conductivity type with a base region of a second conductivity disposed between the first and second stacks.

These and other embodiments of the present invention are discussed further below.

### BRIEF DESCRIPTION OF THE DRAWINGS

The present invention is illustrated by way of example, and not limitation, in the figures of the accompanying drawings, in which:

FIG. 1A is a schematic diagram showing a layer structure for a conventional QC laser in an InP material system;

FIG. 1B is a schematic diagram showing typical electronic conduction band energy levels of a conventional QC laser;

FIG. 2A is a schematic diagram showing a layer structure for a QC laser in an InP material system according to an embodiment of the present invention;

FIG. 28 is a schematic diagram showing a layer structure for a QC laser in a GaAs material system according to a further embodiment of the present invention;

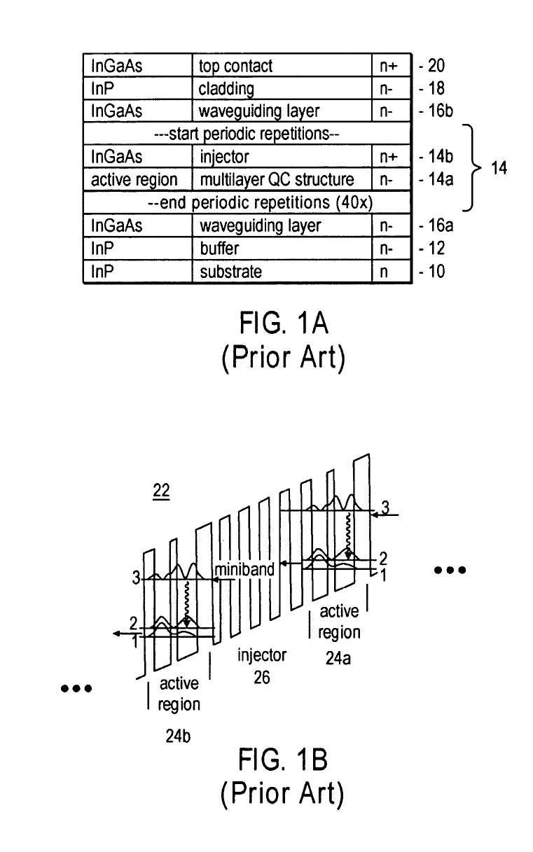

FIG. 3 shows an example of an internally-biased QC laser in which an active region/injection region multilayer, collector and emitter regions and tunnel junctions of a waveguide core are periodically repeated in accordance with an embodiment of the present invention;

FIG. 4 is a schematic diagram showing energy bands of two stages of an active core for a QC laser configured according to an embodiment of the present invention

FIG. 5A shows an optical chemical sensing system using a bipolar laser source in accordance with an embodiment of the present invention; and

FIG. 5B shows an imaging system using a bipolar laser source configured in accordance with an embodiment of the present invention.

### DETAILED DESCRIPTION

Described herein is a QC laser having a first stack of semiconductor layers of a first conductivity type, an active region/injection region multilayer, and a base region disposed between the first stack of semiconductor layers and the active region/injection region multilayer, the base region containing at least one layer of a second conductivity type. Hereinafter, the active region/injection region multilayer will be referred to as the active/injection region. The active/injection region is made up of a multilayer active region of QC materials (for example, GaInAs and AlInAs) and a multilayer injector region as further discussed below.

A further embodiment of the present invention provides a laser with a plurality of active/injection regions of a first conductivity type, each active/injection region having two or more coupled quantum wells having at least a second and third energy level for charge carriers of the first conductivity type, with the third energy level being higher in energy than the second energy level, and a plurality of base layers of a second conductivity type separating the active/injection regions from one another. Hence, in various embodiments the present invention provides a bipolar QC laser. As discussed below, a bipolar QC laser configured in accordance with the present invention may be used as part of a sensing system and/or an imaging system.

A QC laser configured in accordance with the present invention may be manufactured by forming (e.g., by epitaxial growth) a first stack of semiconductor layers of a first conductivity type, forming abase region of a second conductivity type above the first stack of semiconductor layers, and forming an active/injection region above the base region. Alternatively, or in addition, a QC laser configured in accordance with the invention may be created by forming a first and second stack of semiconductor layers of a first conductivity type and forming a base region of a second conductivity type between the first and second stack. Still another method for manufacturing a bipolar QC laser in accordance with the present invention includes depositing stacks of semiconductor layers to form the above-described structures by chemical vapor deposition (CVD).

In various embodiments of the present invention, at least one p-doped layer may be inserted in a waveguide of an n-type QC laser structure. Alternatively, at least one n-doped layer may be inserted in the waveguide of a p-type QC laser structure. In either case, the result is a bipolar QC laser.

Either of the above-described structures can modify the built-in electrical potentials of the heterostructure active/injection region and achieve laser operation with a lower external bias voltage than is typically employed for unipolar QC lasers. The reduction in the operating voltage can improve efficiencies for a bipolar device over its unipolar counterpart by reducing the amount of electrical power that needs to be employed for laser operation. The more efficient the laser, the more cost effective it can be packaged and can result in practical lasers finding many new applications.

Although applicable to all QC lasers and not limited to the energy of the photons or wavelength of operation, some examples given herein will be specific to mid-IR lasers with wavelengths between about 2 μm and about 60 μm, in particular about 3 μm to about 20 μm and more specifically between about 3.5 μm to about 15 μm. Such mid-IR lasers can be based on layers of material grown in sets of cascaded p-n junctions, where each p-n junction includes at least one active/injection region. The active/injection region can be designed to be in the depletion region of the p-n junction in order to balance the built-in potential of the quantum well heterostructure with a field of opposite sign generated by the spatial charge distribution of the dopants. Each of the cascaded p-n junctions can be separated from one another by a spacer layer, the purpose of which is to help confine the carriers away from the active wells of the active/injector regions so to enhance the screening effect and lower optical losses. The complete set of cascaded p-n junctions with interleaved active/injection regions (i.e., the active core of the bipolar laser device) can be embedded in low-doped waveguide and cladding layers.

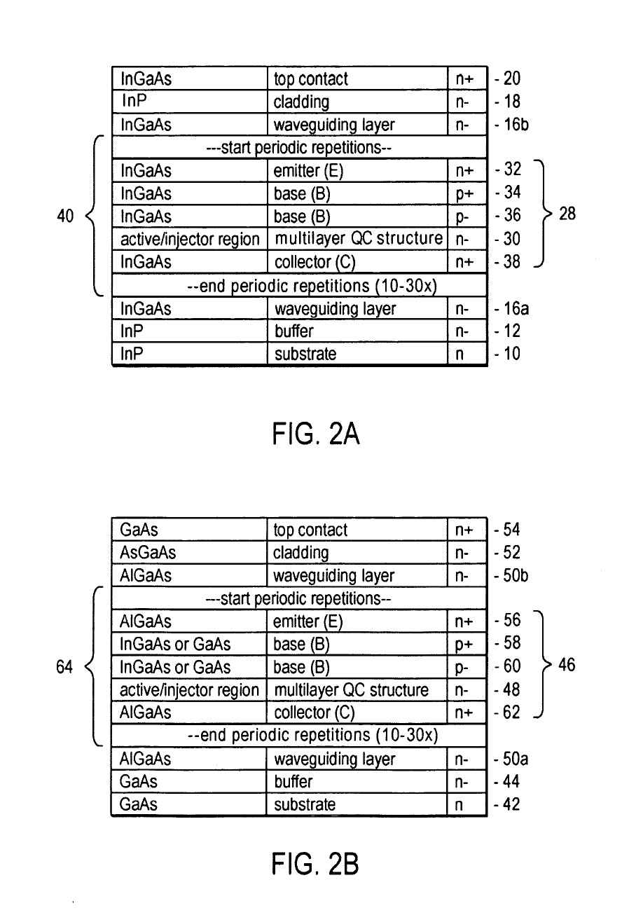

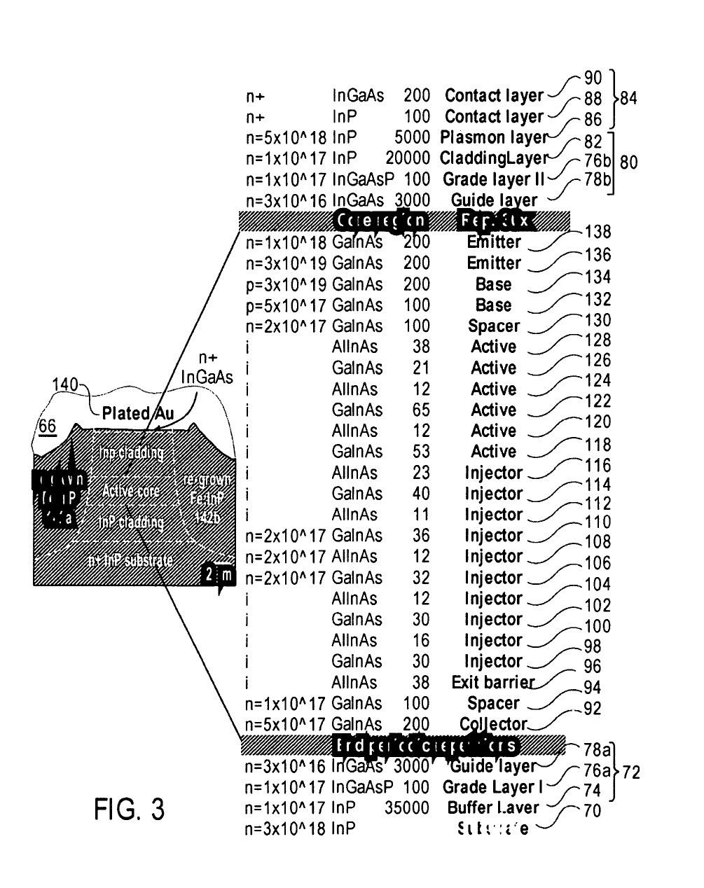

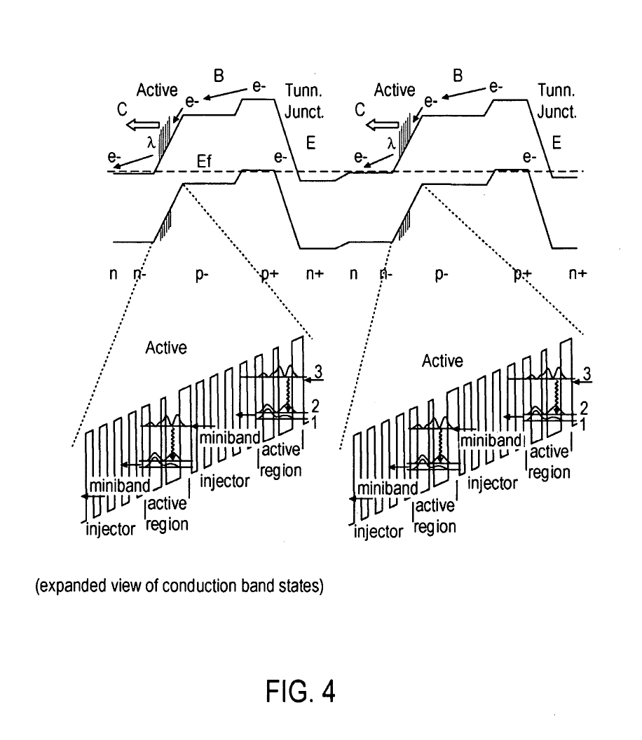

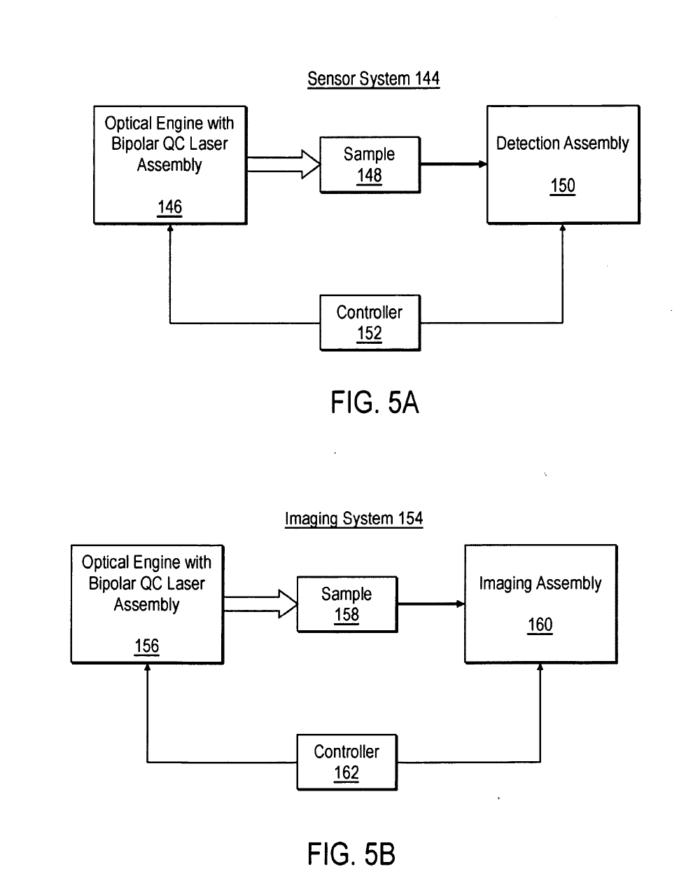

A typical layer structure for a QC laser configured in accordance with the present invention is shown in FIG. 2A. The layers indicated in this chart may be sequentially and epitaxiaily grown on a semiconductor substrate, for example by CVD, metal-organic CVD (MOCVD), a high-throughput, high-yield manufacturing technique, atomic layer deposition (ALD) or similar process. Other methods of epitaxial growth that can be used include vapor phase epitaxy (VPE), molecular beam epitaxy (MBE), and liquid phase epitaxy (LPE).

As shown, an n-type MP substrate 10 serves as a foundational layer and an n⁻-type InP buffer layer 12 is grown thereover. Each multilayer p-n junction structure 28 with its respective active/injector region 30 of the laser is disposed between n⁻-type InGaAs waveguide layers 16a, 16b. An n-type InP cladding layer 18 and an n⁺-type InGaAs top contact layer 20 complete the structure,

Each multilayer p-n junction structure 28 includes an n⁺ InGaAs emitter region 32, a p⁺ InGaAs base region 34, a p⁻ InGaAs base region 36, a respective active/injector region 30 (made up of a multilayer of QC materials, for example, InGaAs and InAlAs), and an n⁺ InGaAs collector 38. The entire active core 40 may include between 10-30 or more such p-n junction structures 28 arranged successively and, optionally, separated from one another by spacer regions (not shown in this illustration, but refer to FIG. 3).

FIG. 2B shows a further embodiment of a bipolar laser configured in accordance with the present invention for an AlGaAs/GaAs system. This example includes 10-30 stages and is designed to operate at a wavelength of approximately 8.5 μm. As shown, an n-type GaAs substrate 42 serves as a foundational layer and an n⁻-type GaAs buffer layer 12 is disposed thereover. Each multilayer p-n junction structure 46 with its respective active/injector region 48 of the laser is disposed between n⁻-type AlGaAs waveguide layers 50a, 50b. An n⁻-type AlGaAs cladding layer 52 and an n⁺-type GaAs top contact layer 50 complete the structure.

Each multilayer p-n junction structure 46 includes an n⁺ AlGaAs emitter region 56, a p⁺ InGaAs or GaAs base region 58, a p⁻ InGaAs or GaAs base region 60, a respective active/injector region 48 (made up of a multilayer of QC materials, for example, InGaAs and InAlAs), and an n⁺ AlGaAs collector 62, As noted, the entire active core 64 may include between 10-30 or more such p-n junction structures 46 arranged successively and, optionally, separated from one another by spacer regions (not shown in this illustration, but refer to FIG. 3).

FIG. 3 shows an example of an internally-biased. QC laser 66 including an active core 68 consisting of thirty periodic repetitions of active/injector region multilayers, respective col lector, emitter and base regions and tunnel junctions, in accordance with an embodiment of the present invention. Waveguide cladding and contact layers are also illustrated in the layout. The specified layer thicknesses for the active core layers are designed to achieve lasing at approximately 8.2-8.5 μm. Although shown with thirty repetitions or stages, the active core may include “n” stages, where n is

a number between 1-100 or more. Further, a different operating wavelength can be achieved by modifying the electronic states in the active core by changing the thicknesses of the wells and barriers. Other material systems which can be used for the laser device include GaAs/AlGaAs, InSbAs/InAs, and GaN/InGaN.

As shown in the illustration, the QC laser 66 is formed on an n⁺ InP substrate 70 with a doping concentration of n=3×10¹⁸ cm⁻³. A lower cladding layer 72 includes an n⁻ InP butler layer 74 approximately 35,000 nm thick with a doping concentration of n=1×10¹⁷ cm⁻³, an n⁻ InGaAsP grade layer 76a approximately 100 nm thick with a doping concentration of n=1×10¹⁷ cm⁻³, and an n⁻ InGaAs waveguiding layer 78 approximately 3000 nm thick with a doping concentration of n=3×10¹⁶ cm⁻³. The repeating active core 68 is disposed over the lower cladding layer 72. An upper cladding layer 80 is disposed over the active core 68 and includes an if InGaAs waveguiding layer 78b approximately 3000 nm thick with a doping concentration of n=3×10¹⁶ cm⁻³, an n⁻ InGaAsP grade layer 76b approximately 100 μm thick with a doping concentration of n=1×10¹⁷ cm⁻³, and an n⁻ InP cladding layer 82 approximately 20,000 nm thick with a doping concentration of n=1×10¹⁷ cm⁻³. A top contact layer 84 is disposed over the upper cladding layer 80 and includes an iv InP surface plasmon layer 86 approximately 5000 nm thick with a doping concentration of n=5×10¹⁸ cm⁻³, an n⁺ InP contact layer 88 approximately 100 nm thick, and an n³⁰ InGaAs contact layer 90 approximately 200 nm thick.

As shown in the illustration, each stage of the active core 68 includes, from bottom to top, an n⁺ Gain As collector layer 92 approximately 200 nm thick with a doping concentration of n=5×10¹⁷ cm⁻³, an n Gain As spacer layer 94 approximately 100 nm thick with a doping concentration of n=1×10¹⁷ cm⁻³, an AlInAs exit harrier layer 96 approximately 38 nm thick, a GaInAs injector layer 98 approximately 30 nm thick, an AlInAs injector layer 100 approximately 16 nm thick, a GaInAs injector layer 102 approximately 30 nm thick, an AlInAs injector layer 104 approximately 12 nm thick, an n⁻ GaInAs injector layer 106 approximately 32 nm thick with a doping concentration of n=2×10¹⁷ cm⁻³, an n⁻ AlInAs injector layer 108 approximately 12 nm thick with a doping concentration of n=2×10¹⁷ cm⁻³, an n* GaInAs injector layer 110 approximately 36 nm thick with a doping concentration of n=2×10¹⁷ cm⁻³, an AlInAs injector layer 112 approximately 11 nm thick, a GaInAs injector layer 114 approximately 40 nm thick, an AlInAs injector layer 116 approximately 23 nm thick, a GaInAs active region layer 118 approximately 53 nm thick, an AlInAs active region layer 120 approximately 12 nm thick, an n⁻ GaInAs active region layer 122 approximately 65 nm thick, an AlInAs active region layer 124 approximately 12 nm thick, a GaInAs active region layer 126 approximately 21 nm thick, an AlInAs active region layer 128 approximately 38 μm thick, an n⁻ GaInAs spacer layer 130 approximately 100 nm thick with a doping concentration of n=2×10¹⁷ cm⁻³, a p⁺ GaInAs base layer 132 approximately 100 nm thick with a doping concentration of p=5×10¹⁷ cm⁻³, a p=GaInAs base layer 134 approximately 200 nm thick with a doping concentration of p=3×10¹⁹ cm⁻³, an n⁺ GaInAs emitter layer 136 approximately 200 nm thick with a doping concentration of n=3×10¹⁹ cm⁻³, and an n⁺ GaInAs emitter layer 138 approximately 200 nm thick with a doping concentration of n=1×10¹⁸ cm⁻³.

In the example shown in FIG. 3, two active/injection regions are included in each periodic repetition in the waveguide core. Alternatively, more than two active/injection regions can be included between each base and collector layers in order to increase the ratio between the number of active/injector regions and the number of highly-doped tunnel junctions, so as to have a lower average doping of the waveguide core and, therefore, a lower optical absorption loss.

The QC laser 66 may be contacted using a plated Au contact 140 to the contact layer 84, as shown. Further, the laser 66 may be surrounded by semi-insulating Fe:InP regions 142a and 142b, disposed over the substrate and around the cladding and active core regions.

A simplified image of the periodically repeated potential band structure for a QC laser configured in accordance with the present invention is illustrated in FIG. 4. The upper trace represents the conduction band and the lower trace the valence band of the semiconductor material. Eᵣ is the Fermi level. The narrow vertical lines indicate the active core region (which may be fabricated with the various layer thicknesses described above with reference to FIG. 3) where the optical radiation is generated. Also indicated in the illustration is the flow of electrons (represented as e⁻) that generates the optical radiation (indicated with the symbol λ).

In this example, a current can be generated by forward biasing the emitter-base (E-B) junction and having the bias between B and collector (C) maintained so as to keep the QC structure (i.e., the active core region) close to its operating bias potential. The emitter and collector regions are semiconductor regions of the same conductivity type, n-type in this example, doped to different levels as shown in the band structure diagram of FIG. 4.

The emitter and collector may also have the same doping concentration and be the same layer, serving as the collector for one active region and the emitter for the next active region in sequence. The base layers are doped of a second conductivity type and are generally thinner and more highly doped, for example up to ten times that of the emitter/collector regions.

Not shown in FIG. 4 are optional spacer layers that can be adjacent to one or both sides of the active region. The spacer layers may be undoped, unintentionally doped, compensated, or lightly doped n-type or p-type regions. The spacer layers may have a bandgap energy higher than the quantum wells of the active region.

An optimal doping concentration and bias may be determined experimentally to minimize the dissipated power and to keep the band structure aligned. This optimal condition can depend on the specific active region design. As shown, a tunnel junction can be used between the emitter (E) and the base (B) to regenerate the charge carriers that are going to be injected in each following stage. The thickness of the tunnel junction may be approximately 30 nm. The total number of stages with tunnel junction repetitions is optimized for efficiency and to minimize trade-off with optical power.

The efficiency of a laser can be described as its optical power output (P) divided by its electrical power input of voltage times current (V×I). Comparing the efficiency of a bipolar QC laser of the present invention to that of a conventional unipolar QC laser, the increase in conversion efficiency will be approximately proportional to the ratio of the bias voltage of the unipolar QC laser to the bias voltage of the bipolar QC laser, assuming that the optical power (P) and current threshold (Iₜₕ) for the bipolar and unipolar lasers are comparable. More realistically, the current threshold may be higher for the bipolar QC laser due to the increase in optical losses caused by the opposite conductivity type layers, p-type in this example, but the decrease of the bias voltage can still make these devices more efficient than the traditional unipolar QC laser.

The key role of the doping concentration and profile distribution of p-dopants in a bipolar QC laser configured in accordance with the present invention can determine the efficiency improvement. Optimal p-doping distribution can depend on the particular structure designed, but for example can be selected from the following:
dopant concentration: 1×10¹⁶−3×10¹⁹ cm⁻³,
spatial spreading of dopants: smaller than or equal to about 10 nm,
dopant type: p (i.e., C, Be, Zn, Mg),
spacing layers thickness: greater than or equal to about 10 nm,
typical fields in the depletion region: 10 kV−100 kV.
number of active regions: 2-100;
   or more specifically:
dopant concentration: 5×10¹⁶−1×10¹⁸ cm⁻³,
spatial spreading of dopants: about 10 nm.
dopant type: p (i.e., C, Be, Mg, Zn for InP-based materials),
spacing layers thickness: greater than or equal to about 10 nm,
typical fields in the depletion region: 20 kV−70 kV,
number of active regions: 5-35.

The bipolar QC lasers described herein can be used as optical engines for a number of sensing and imaging systems. One example, is a chemical sensor having at least one bipolar QC laser configured in accordance with the present invention, as shown in FIG. 5A. In sensor arrangement 144, the laser light from an optical engine 146 passes through a test sample 148 and the laser power transmitted through the sample is detected by a detection assembly 150, The amount of power absorbed by the sample under test depends on the number of molecules present in the sample, the optical cross section of the molecules in the sample, and the optical path length of the sample cell. The optical engine 146 can include one or more bipolar QC lasers at various wavelengths, optics, and drive electronics. The detection assembly 150 can include receiving optics, optical, mechanical, or acoustic sensors, and drive electronics. The system is operated under the control of a controller 152.

Other applications for a bipolar QC laser-based optical engine include remote sensing, surveillance, chemical detection and vision systems. For example, an active imaging system 154 using at least one bipolar QC laser is shown in FIG. 5B. This active imaging system can use a single or multiple wavelength laser to illuminate a test sample. The optical engine 156 can include one or more bipolar QC lasers, an x-y scanner, drive and pulse conditioning electronics, and optics. The sample 158 can be placed close to the laser assembly or at a distance greater than about 0.1 m. The laser beam can be collimated and focused or aimed at a test sample or target. The reflected spectroscopic properties of the sample or target can be received by the imaging assembly 160. The imaging assembly may include parabolic mirrors, telescopic optics and a detector or imaging camera. The system can also probe non-spectroscopic properties such as diffracted, diffused reflection or scattered laser signal from the test sample or target. The imaging system can include image processing algorithms to aid in the interpretation and representation of the test sample or target. The system is operated under the control of a controller 162.

Although the present invention has been described in detail with reference to certain specific configurations thereof, other versions are possible. Therefore, the spirit and scope of the invention should not be limited to the specific embodiments of the invention described above.

What is claimed is:

1. A quantum cascade laser, comprising:
a first stack of semiconductor layers of a first conductivity type,
an active core of semiconductor layers, and
a base between the first stack and the active core, the base containing at least one layer of a second conductivity type.

2. The quantum cascade laser of claim 1, wherein the first stack comprises an emitter.

3. The quantum cascade laser of claim 1, wherein the first stack and the base form a tunnel junction.

4. The quantum cascade laser of claim 1, wherein the active core of semiconductor layers comprises a plurality of active regions made up of quantum cascade materials separated by injector regions.

5. The quantum cascade laser of claim 4, further comprising second stacks of semiconductor layers of the first conductivity type between each of the plurality of active regions.

6. The quantum cascade laser of claim 5, wherein each of the second stacks comprises a collector for one of the plurality of active regions and an emitter for an adjacent one of the active regions.

7. The quantum cascade laser of claim 4, wherein the number of active regions is between 2 and 100, inclusive.

8. The quantum cascade laser of claim 4, wherein the number of active regions is between 5 and 35, inclusive.

9. The quantum cascade laser of claim 1, wherein the base further comprises a more heavily doped layer of the second conductivity type and a more lightly doped layer of the second conductivity type.

10. A laser, comprising a plurality of active/injection regions of a first conductivity type, each active/injection region including two or more coupled quantum wells having at least a second and third energy level for charge carriers of the first conductivity type, the third energy level being higher in energy than the second energy level; and a plurality of base layers of a second conductivity type each of the base layers separating respective pairs of the active/injection regions from one another.

11. The laser of claim 10, further comprising electrical contacts coupled to apply a voltage across the active/injection regions.

12. The laser of claim 11, wherein at least some of the charge carriers of the first conductivity type undergo a radiative transition from the third energy level to the second energy level within at least one of the active/injection regions.

13. The laser of claim 12, wherein the charge carriers of the first conductivity type are transferred from the second energy level of each preceding one of the active/injection regions to the third energy level of a succeeding one of the active/injection regions, said second energy level of each preceding one of the active/injection regions being higher in energy than said third energy level of each succeeding one of the active/injection regions.

14. The laser of claim 11, further comprising tunnel junctions between respective pairs of the active/injection regions.

15. The laser of claim 14, wherein each tunnel junction regenerates carriers of first conductivity type.

16. A sensing system, comprising an optical engine having at least one quantum cascade laser that includes a first stack of semiconductor layers of a first conductivity type, an active/injection region of semiconductor layers, and a base region between the first stack of semiconductor layers and the active/injection region, the base region containing at least one layer of a second conductivity type; a cell configured to contain a test sample; and a detection assembly configured to measure, responsive to irradiation of the test sample with light from the QC laser, changes in at least one of optical transmission, absorption, or reflection of the test sample, or an intrinsic or extrinsic physical parameter of the test sample.

17. The sensing system of claim 16, wherein the test sample is a remote target positioned more than about 0.1 m away from the laser.

18. A quantum cascade laser, comprising a p-n junction disposed adjacent to an active/Injection region of semi conductor layers.

19. A method for manufacturing a quantum cascade laser, comprising:
forming a first stack of semiconductor layers of a first conductivity type;
forming a base region above the first stack of a second conductivity type; and
forming an active/injection region above the base region.

20. The method of claim 19, wherein the active/injection region comprises a second stack of semiconductor layers of the first conductivity type.
